(19) United States
(12) Patent Application Publication
(10) Pub. No.: US 2025/0006518 A1
(43) Pub. Date: Jan. 2, 2025

(54) BOTTOM ETCH PROCESS FOR CONTACT PLUG ANCHORING

(71) Applicant: Applied Materials, Inc., Santa Clara, CA (US)

(72) Inventors: Shiyu YUE, Santa Clara, CA (US); Wei LEI, San Jose, CA (US); Yu LEI, Belmont, CA (US); Ju Hyun OH, San Jose, CA (US); Zhimin QI, Santa Clara, CA (US); Sahil Jaykumar PATEL, Sunnyvale, CA (US); Yi XU, San Jose, CA (US); Aixi ZHANG, Santa Clara, CA (US); Bingqian LIU, Santa Clara, CA (US); Cong TRINH, Santa Clara, CA (US); Xianmin TANG, San Jose, CA (US); Hayrensa ABLAT, Santa Clara, CA (US)

(21) Appl. No.: 18/753,006

(22) Filed: Jun. 25, 2024

Related U.S. Application Data
(60) Provisional application No. 63/523,586, filed on Jun. 27, 2023.

(51) Int. Cl. H01L 21/67; H01L 21/321; H01L 21/768; H01L 23/532

(52) U.S. Cl. CPC H01L 21/67034; H01L 21/3212; H01L 21/76814; H01L 21/76877; H01L 23/53266; H01L 21/67167

(57) ABSTRACT

Embodiments herein relate to a method, semiconductor device structures, and multi-chamber processing system for exposing a semiconductor device structure to an oxidizing plasma to form an oxide layer on at least one electrical connection formed in at least one feature formed within a dielectric layer of the semiconductor device structure, performing an etch process to remove the oxide layer and form an etch recess between a portion of the electrical connection and the dielectric layer At least a portion of the etch recess extends underneath at least a portion of the dielectric layer, and filling the at least one feature and the etch recess with a metal material.

### CROSS-REFERENCE TO RELATED APPLICATIONS

This application claims the benefit of United Stated Provisional Patent Application Ser. No. 63/523,586 filed Jun. 27, 2023, which is hereby incorporated by reference.

### TECHNICAL FIELD

Embodiments described herein generally relate to semiconductor device fabrication. More specifically, embodiments of the present disclosure relate to semiconductor devices that includes low resistance contacts and methods of forming the same.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Microelectronic devices are fabricated on a semiconductor substrate as integrated circuits in which various conductive layers are interconnected with one another to permit electronic signals to propagate within the device. An example of such a device include memory (e.g., DRAM) and logic devices, including both planar and three-dimensional structures. An example of a three-dimensional structure is a finFET or MOSFET devices.

In a traditional middle-end-of-the-line (MEOL) contact formation process, a feature, such as a via or trench is fabricated in the semiconductor substrate. MEOL contact allow connections between front-end-of-the-line (FEOL) semiconductor structures and back-end-of-the-line (BEOL) interconnects. Contacts with low resistance are desirable in semiconductor devices. However, when a MEOL contact has a relatively high resistance, a poor connection is created at the MEOL contact, which reduces the overall performance of the packaged semiconductor structures.

Conventional MEOL and BEOL electrical connections, such as contacts, interconnects, and the like are formed by filling a feature such as a cavity, trench, or via with a conductive material. Then the feature is filled with a metal material to form a plug fill layer that serves as an interconnect between layers of the device. The initially deposited metal material typically includes an undesired overburden formed on a field region of the substrate. A chemical mechanical polishing (CMP) process is used to remove the overburden. However, due to poor structural bonding between the plug fill layer and the underlying metal layer, the entire plug fill layer is pulled out, and thus separated from the underlying metal layer, during the CMP process.

Current state of art approaches to prevent the plug fill pull out issue is to use plasma enhanced atomic layer deposition (PEALD) and/or physical vapor deposition (PVD) processes to improve bonding between the layers, which leads to a low throughput, complex integration flows, and high cost.

Therefore, there is a need in the art for a process that is used to form reliable contact structures and solve the problems described above.

### SUMMARY

In one or more embodiments, a method includes exposing a semiconductor device structure to an oxidizing plasma to form an oxide layer on at least one electrical connection formed in at least one feature formed within a dielectric layer of the semiconductor device structure, performing an etch process to remove the oxide layer and form an etch recess between a portion of the electrical connection and the dielectric layer, wherein at least a portion of the etch recess extends underneath at least a portion of the dielectric layer, and filling the at least one feature and the etch recess with a metal material.

In one or more embodiments, A multi-chamber processing system includes a controller; and a memory for storing instructions, which, when executed by the controller, causes the controller to perform a method for treating an electrical connection formed in a feature formed in a dielectric layer of a semiconductor structure, the method including exposing a semiconductor device structure to an oxidizing plasma to form an oxide layer on at least one electrical connection formed in at least one feature formed within a dielectric layer of the semiconductor device structure, performing an etch process to remove the oxide layer and form an etch recess between a portion of the electrical connection and the dielectric layer, wherein at least a portion of the etch recess extends underneath at least a portion of the dielectric layer; and filling the at least one feature and the etch recess with a metal material.

In one or more embodiments, A semiconductor device structure includes a device substrate having a frontside opposite a backside, a dielectric layer formed over the frontside of the device substrate, a feature formed within the dielectric layer, the feature extending through the dielectric layer and to a portion of an underlying layer that forms part of an electrical connection formed within the device substrate; and an etch recess formed between a portion of the electrical connection and an overlying portion of the dielectric layer.

### BRIEF DESCRIPTION OF THE DRAWINGS

So that the manner in which the above-recited features of the present disclosure can be understood in detail, a more particular description of the aspects, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 illustrates a schematic top view of a multi-chamber processing system 100 according to one or more embodiments.

FIG. 2 is a flow diagram depicting a method of forming an electrical connection of a semiconductor structure, according to one or more of the embodiments described herein.

FIGS. 3A-3F illustrate views of various stages of forming an electrical connection of a semiconductor structure in accordance with one or more embodiments described herein

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Middle-end-of-the-line (MEOL) and back-end-of-the-line (BEOL) electrical connections, such as contacts, interconnects, and the like are formed by filling a feature such as a cavity, trench, or via with a conductive material that is in contact with an underlying metal layer. To form the interconnect the feature is filled with a metal material to form a metal plug. The initially deposited metal material will include an undesirable over burden layer formed on a field region of the substrate. A chemical mechanical polishing (CMP) process is used to remove the overburden. However, because there is typically poor adhesion and/or bonding between the metal plug formed within the feature, the entire metal plug can be pulled out, and thus separated from an underlying metal layer, during the CMP process. Embodiments of the present disclosure relate to a method and apparatus for forming an interconnect that at least will not become separated from and lose contact with the underlying layer it is formed on during a CMP process. In particular, embodiments of the present disclosure relate to forming an etch recess in the feature to anchor the metal plug. For example, separate process sequences for forming an oxide layer within the feature, and forming the etch recess that may be performed in a same processing chamber.

Embodiments of the present disclosure include many potential pathways to anchor the plug metal layer, which will include etching the bottom metal layer.

### Multi-Chamber Processing System Example

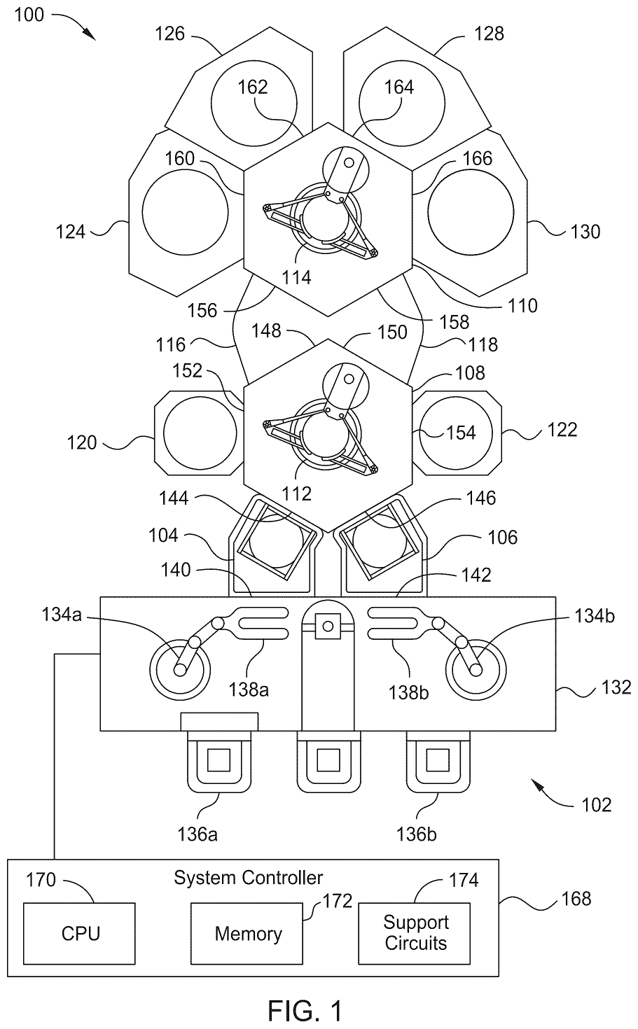

FIG. 1 illustrates a schematic top view of a multi-chamber processing system 100 according to one or more embodiments. The multi-chamber processing system 100 can be used for creating a bottom lateral recess (an etch recess) in a device substrate to anchor a metal material of an MEOL or BEOL electrical connection during a chemical mechanical polishing (CMP) process. The multi-chamber processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the multi-chamber processing system 100 can be processed in and transferred between the various chambers without exposing the substrates to an ambient environment exterior to the multi-chamber processing system 100, for example, an atmospheric ambient environment such as may be present in a fab. The substrates can be processed in and transferred between the various chambers maintained at a low pressure, for example, less than or equal to about 300 Torr, or a vacuum environment without breaking the low pressure or vacuum environment among various processes performed on the substrates in the multi-chamber processing system 100. Accordingly, the multi-chamber processing system 100 may provide for an integrated solution for processing of substrates.

Examples of multi-chamber processing systems that may be suitably modified in accordance with the teachings provided herein include the Endura®, Producer® or Centura® integrated multi-chamber processing systems or other suitable multi-chamber processing systems commercially available from Applied Materials, Inc., located in Santa Clara, California. It is contemplated that other multi-chamber processing systems (including those from other manufacturers) may be adapted to benefit from aspects described herein.

In the illustrated example of FIG. 1, the factory interface 102 includes a docking station 132 and factory interface robots 134a-b to facilitate transfer of substrates. The docking station 132 is adapted to accept one or more front opening unified pods (FOUPs) 136a-b. In some examples, each factory interface robot 134a-b generally includes a blade 138a-b disposed on one end of the respective factory interface robot 134a-b adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, the transfer chambers 108, 110, the holding chambers 116, 118, and the processing chambers 120, 122, 124, 126, 128, 130 may be fluidly coupled to a gas and pressure control system (not specifically illustrated). The gas and pressure control system can include one or more gas pumps (for example, turbo pumps, cryo-pumps, roughing pumps) gas sources, various valves, and conduits fluidly coupled to the various chambers. In operation, the factory interface robot 134a-b transfers a substrate from the FOUP 136a-b through the port 140 or 142 to the load lock chamber 104 or 106. The gas and pressure control system then pumps down the load lock chamber 104 or 106. The gas and pressure control system further maintains the transfer chambers 108, 110 and the holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, and the processing chambers 126, 128, 130 can be capable of performing respective growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Volta™ CVD/ALD chamber, or Encore™ PVD chambers available from Applied Materials of Santa Clara, Calif.

A system controller 168 is coupled to the multi-chamber processing system 100 for controlling the multi-chamber processing system 100 or components thereof. For example, the system controller 168 may control the operation of the multi-chamber processing system 100 using a direct control of the processing chambers 104, 106, 108, 110, 116, 118, 120, 122, 124, 126, 128, 130 of the multi-chamber processing system 100 or by controlling controllers associated with the processing chambers 104, 106, 108, 110, 116, 118, 120, 122, 124, 126, 128, 130. In operation, the system controller 168 enables data collection and feedback from the respective chambers to coordinate performance of the multi-chamber processing system 100.

The system controller 168 generally includes a central processing unit (CPU) 170, memory 172, and support circuits 174. The CPU 170 may be one of any form of a general-purpose processor that can be used in an industrial setting. The memory 172, non-transitory computer-readable medium, or machine-readable storage device, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. That is, the computer program product is tangibly embodied on the memory 172 (or non-transitory computer-readable medium or machine-readable storage device). When the computer instruction code is executed by the CPU 170, the CPU 170 controls the chambers to perform processes in accordance with the various methods.

The instructions in memory 172 may be in the form of a program product, such as a program that implements the methods of the present disclosure. In one example, the disclosure may be implemented as a program product stored on a computer-readable storage media for use with a computer system. The program(s) of the program product define functions of the implementations (including the methods described herein). Thus, the computer-readable storage media, when carrying computer-readable instructions that direct the functions of the methods described herein, are implementations of the present disclosure. The system controller 168 is configured to perform methods such as the method 200 stored in the memory 172.

### Processing Sequence Example

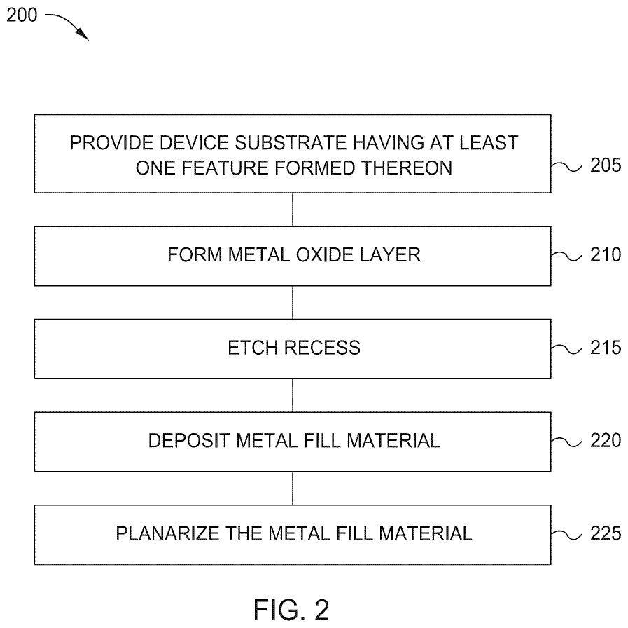

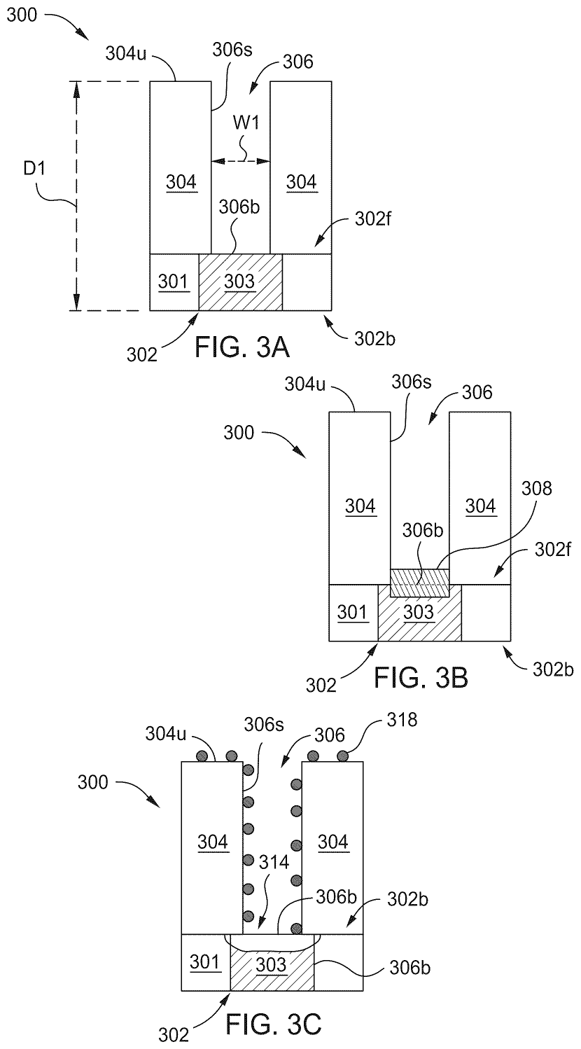

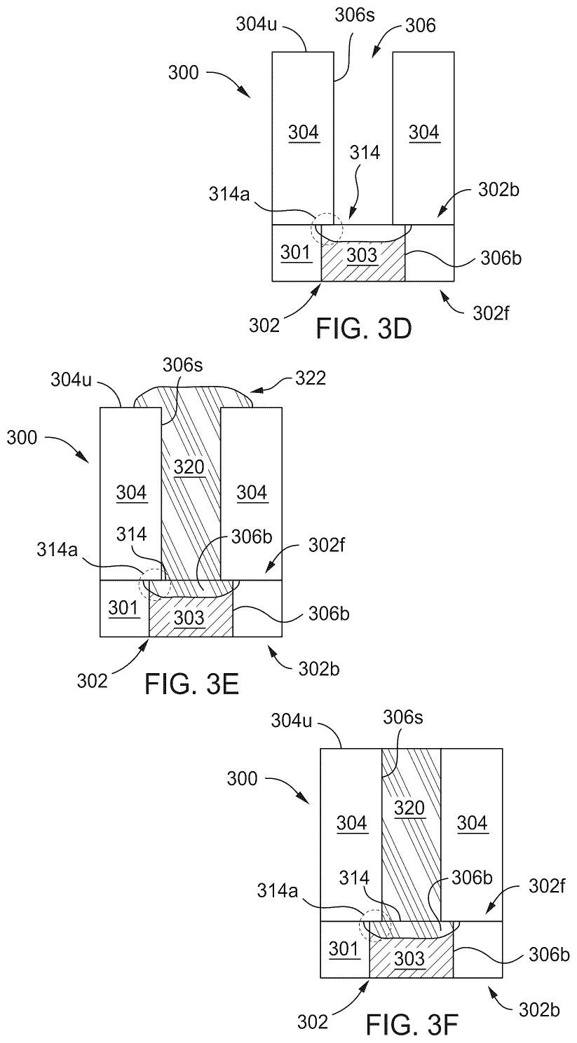

FIG. 2 is a flow diagram depicting a method of forming an electrical connection of a semiconductor device structure, according to one or more of the embodiments described herein. FIGS. 3A-3F illustrate views of various stages of forming an electrical connection of a semiconductor structure in accordance with one or more embodiments described herein. Although FIGS. 3A-3F are described in relation to the method 200, the structures disclosed in FIGS. 3A-3F are not limited to the method 200, but instead may stand alone as structures independent of the method 200. Similarly, although the method 200 is described in relation to FIGS. 3A-3F, the method 200 is not limited to the structures disclosed in FIGS. 3A-3F but instead may stand alone independent of the structures disclosed in FIGS. 3A-3F. It should be understood that FIGS. 3A-3F illustrate only partial schematic views of the semiconductor device structure 300, and the semiconductor device structure 300 may contain any number of transistor sections and additional materials having aspects as illustrated in the figures. It should also be noted that although the method 200 illustrated in FIG. 2 is described sequentially, other process sequences that include one or more operations that have been omitted and/or added, and/or has been rearranged in another desirable order, fall within the scope of the embodiments of the disclosure provided herein.

The term “substrate” as used herein refers to a layer of material that serves as a basis for subsequent processing operations. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

Referring to FIG. 2, at operation 205, a semiconductor device structure 300 having a feature formed therein is provided. FIG. 3A illustrates a cross-sectional view of the semiconductor device structure 300 during intermediate stages of manufacturing corresponding to the operation 205. The semiconductor device structure 300 includes a device substrate 302 having one or more layers formed thereon, for example, dielectric layers 301 and 304 as is shown in FIG. 3A. The device substrate 302 may be or include a bulk semiconductor substrate, a semiconductor-on-insulator (SOI) substrate, or the like, which may be doped (e.g., with a p-type dopant or an n-type dopant) or undoped. The actual base substrate on which the one or more layers are formed is not shown in FIGS. 3A-3F for simplicity of discussion. In some embodiments, the semiconductor material of the base substrate portion of the device substrate 302 may include an elemental semiconductor, for example, such as silicon (Si) or germanium (Ge); a compound semiconductor including, for example, silicon carbide, gallium arsenide, gallium phosphide, indium phosphide, indium arsenide, and/or indium antimonide; an alloy semiconductor including, for example, SiGe, GaAsP, AllnAs, GalnAs, GalnP, and/or GalnAsP; a combination thereof, or the like. The device substrate 302 may include additional materials, for example, silicide layers, metal silicide layers, metal layers, dielectric layers, etch stop layers, interlayer dielectrics, or a combination thereof.

The device substrate 302 may further include integrated circuit devices (not shown). As one of ordinary skill in the art will recognize, a wide variety of integrated circuit devices such as transistors, diodes, capacitors, resistors, the like, or combinations thereof may be formed in and/or on the device substrate 302 to generate the structural and functional requirements of the design for the resulting semiconductor device structure 300.

The device substrate 302 has a frontside 302f (also referred to as a front surface) and a backside 302b (also referred to as a back surface) opposite the frontside 302f. The dielectric layers 301 and 304 are formed over the frontside 302f of the device substrate 302. The dielectric layers 301 and 304 may include multiple layers. The dielectric layer 304 includes an upper surface 304u or field region. In some embodiments, the dielectric layers 301 and 304 includes a dielectric material, such as a low k dielectric (SiCOH), silicon oxide, silicon dioxide (SiO₂), silicon nitride (Si₃N₄), silicon carbide (SIC), silicon oxynitride (SiON), aluminum oxide (Al₂O₃), aluminum nitride (AlN), a combination thereof, or multi-layers thereof. In some embodiments, the dielectric layers 301 and 304 consist essentially of silicon oxide. It is noted that the foregoing descriptors for example, silicon oxide, should not be interpreted to disclose any particular stoichiometric ratio. Accordingly, “silicon oxide” and the like will be understood by one skilled in the art as a material consisting essentially of silicon and oxygen without disclosing any specific stoichiometric ratio.

The semiconductor device structure 300 is patterned to form one or more feature(s) 306. The feature 306 may be a high aspect ratio (HAR) feature. In some embodiments, the feature 306 can be selected from, but not limited to, a trench, a via, a hole, a cavity, or a combination thereof. In particular embodiments, the feature is a trench. In other particular embodiments, the feature 306 is a via. In some embodiments, the feature 306 extends from the upper surface 304u of the dielectric layer 304 towards the backside 302b of the device substrate 302. The feature 306 includes sidewall surface(s) 306s that extend from the field region 304u to the backside 302b.

In some embodiments, an electrical connection, such as electrical connection 303 (i.e., underlying metal layer) is formed within the dielectric layer 301 formed at the bottom of the feature 306. The electrical connection 303 may be an interconnect, a contact structure, or the like. The electrical connection 303 is formed in a prior patterning sequence performed prior to forming the dielectric layer 304 and forming feature 306 therein. For example, as shown in FIG. 3A, the electrical connection 303 may be a contact structure that includes a conductive material. The conductive material may be formed of copper (Cu), cobalt (Co), molybdenum (Mo), tungsten (W), tantalum (Ta), titanium (Ti), or ruthenium (Ru), combinations thereof, and/or nitrides thereof. The feature 306 has a first depth “D1” from the upper surface 304u to the backside 302b and a width “W1” between the two sidewall surface(s) 306s. In some embodiments, the depth D1 is in a range of 2 nm to 200 nm. In some embodiments, the width W1 is in a range of 10 nm to 100 nm. In some embodiments, the feature 306 has an aspect ratio (D/W) in a range of 1 to 20.

At operation 210, and as illustrated in FIG. 3B, an oxide layer 308 is formed on the surface of the electrical connection 303. In some embodiments, an oxide layer 308 is formed on the surface of the electrical connection 303 by exposing the semiconductor device structure 300 to an oxidizing plasma (i.e., a plasma oxidation process) to form an oxide layer over the electrical connection 303. In one or more examples, the oxidizing plasma may be an inductively coupled plasma (ICP) or a capacitively coupled plasma (CCP). In one or more embodiments, the oxidizing plasma may be generated from exposure to a hydrogen and oxygen containing process gas. The oxidizing plasma may be generated by co-flowing oxygen and hydrogen, generating a plasma that includes hydrogen and oxygen. In some embodiments, the oxide layer 308 may be a metal oxide material such as tungsten oxide (WOx).

At operation 215, and as illustrated in FIGS. 3C-3D the semiconductor device structure 300 undergoes a etch process that removes the oxide layer 308 and forms an etch recess 314 in the electrical connection 303. The etch process may include performing a chemical soaking process to etch the oxide layer 308 and form the etch recess 314, and then a treatment process to remove residue 318 formed during the etch process.

In one or more examples, the chemical soaking process may include exposing the semiconductor device to an etching gas that includes a metal halide containing gas, such as at least one of, but not limited to, tungsten pentachloride (WCl₅), tungsten hexafluoride (WF₆), molybdenum pentachloride (MoCl₅), molybdenum hexachloride (MoCl₆), molybdenum hexafluoride (MoF₆), or combinations thereof. The soaking process may be performed at a temperature between 20° and 500° C., and a pressure of 3 and 50 Torr for a duration of 30 to 600 seconds.

Advantageously, the chemical soaking process removes the oxide layer 308 and forms the etch recess 314. The etch recess 314 may be a semi-circular cut-out formed in the electrical connection 303. Stated otherwise, the chemical soaking process forms the etch recess 314 (i.e., a semi-circular cut-out) between a portion of the electrical connection 303 and the dielectric layer 304. The etch recess 314 allows the subsequent metal material 320 (FIG. 3E) formed in the feature 306 to be anchored to the dielectric layer 304 within the etch recess 314 by at least the use of the formed anchoring regions 314a, which are discussed further below. The anchoring of the metal material 320 prevents the metal material 320 from being pulled out during a subsequent chemical mechanic polishing (CMP) process. The anchoring of the metal material 320 also allows for a clean interconnection between layers, and therefore, forms an interconnect with a low resistance.

After forming the etch recess 314, due the chemistry of the chemical soaking process, residue 318 (FIG. 3C) may be formed on the semiconductor device structure 300. The residue 318 may be formed on the upper surface 304u, the sidewall surface(s) 306s, and/or on the exposed surface of the electrical connections exposed within the feature 306 (i.e., on the surface of the etch recess 314). The residue 318 may comprise any residue that may be formed due to the soaking process, including, but not limited to, chlorine or fluorine containing contaminants. In one or more examples, the treatment process of operation 215 includes further exposing and treating the semiconductor device structure 300 with a cleaning gas to remove the residue 318 (FIG. 3D). The residue 318 may be removed via a treatment process that includes exposing the portions of the feature 306 to plasma and/or a baking process that includes exposing the feature 306 to the cleaning gas that comprises ions, radicals, and/or neutrals of a hydrogen containing gas. In one or more examples, the treatment process may be performing using a treatment plasma that is a hydrogen based plasma. In one or more embodiments, the treatment plasma may be an ICP plasma or a CCP plasma generated with biased hydrogen. In other embodiments, the treatment plasma may be formed by use of a remote plasma generated using a remote lid assembly for a processing chamber that is able to switch between an CCP plasma and an indirect CCP plasma, a remote plasma source (RPS), or RPL.

In other embodiments, the treatment process may include a baking process. The baking process may include soaking the semiconductor device structure 300 in hydrogen or water and baking the semiconductor device structure 300 at temperature between 20° and 500° C., pressure of 3 and 50 Torr for a duration between 10 and 600 seconds. The baking process may comprise heating the substrate to a temperature greater than room temperature, such as greater than 200° C., such as greater than 300° C.

As shown in FIG. 3D, after performing operation 215, a portion of the etch recess 314 formed in the electrical connection 303 will include the anchoring regions 314a that are positioned under at least a portion of the overlying dielectric layer 304. In some embodiments, the anchoring regions 314a can extend to an edge (e.g., sidewalls of dielectric layer 301) of the opening in which the electrical connection 303 is disposed within. In one or more embodiments, operations 210-215 may be repeated to provide a clean interface for a subsequent deposition of a metal material 320 (FIG. 3E) into the features 306 and to also ensure that the etch recess 314 (i.e., the anchoring regions 314a) are sufficient to anchor the metal material 320.

At operation 230 and as illustrated in FIG. 3E the feature 306 is filled with the metal material 320. FIG. 3E illustrates a cross-sectional view of the semiconductor device structure 300 during intermediate stages of manufacturing corresponding to the operation 230. The metal material 320 can be formed by a bottom-up growth or conformal growth deposition process. For example, in this embodiment, metal material 320 is formed by a selective bottom-up deposition process. In some embodiments, where one or more layers are formed on the sidewall surface(s) 306s and the bottom portion 306b prior to the metal material 320, the metal material 320 may be formed by conformal growth. In some embodiments, where one or more layers are formed on the sidewall surface(s) 306s and the bottom portion 306b prior to the metal material 320, the metal material 320 may formed by bottom-up growth. The metal material 320 may be formed by any suitable deposition process such as atomic ALD, CVD, physical vapor deposition (PVD), or a hybrid ALD/CVD process. In some embodiments, metal material 320 can be a metal selected from a group consisting of molybdenum (Mo), tungsten (W), cobalt (Co), copper (Cu), ruthenium (Ru), or other useful metal. In one example, precursors used during the deposition process may include molybdenum-containing precursors selected from molybdenum chlorides (e.g., MoClₓ [x=2−6]), molybdenum fluorides (MoF₆). In some embodiments, the molybdenum chloride can be or include molybdenum (II) chloride, molybdenum (III) chloride, molybdenum (IV) chloride, molybdenum (V) chloride, molybdenum (IV) chloride, or a combination thereof. In particular embodiments, the molybdenum chloride precursor can be or include molybdenum (V) chloride that is molybdenum pentachloride (MoCl₅). Suitable examples of the metal containing precursor include Mo(NMe₂)₄, MoCl₅, MoF₆, molybdenum tetramethylheptane-3,5-dionato (Mo(thd)₃), Mo(CO)₆, and the like that are used to form a molybdenum containing layer.

In one example, the metal material 320 deposition process includes a CVD process that includes injecting a molybdenum containing precursor (e.g., molybdenum pentachloride (MoCl₅)), hydrogen (H₂) and a carrier gas (e.g., argon (Ar)) into a processing chamber, while maintaining the substrate disposed within the processing chamber at a temperature in a range of about 300 to 425° C. In some embodiments, an ampoule temperature of an ampoule that includes the molybdenum containing precursor, which positioned upstream of the processing chamber environment, is maintained at a lower temperature than the temperature within the processing chamber. For example, the ampoule temperature may be maintained in a range of about 60 to 90° C. In certain embodiments, a pressure within the processing chamber during the deposition process may be maintained in a range of about 5 to 50 Torr.

At the end of operation 230, the metal material 320 fills feature 306, which includes the etched recess 314, as shown in FIG. 3E. In some embodiments, the metal material 320 overfills the feature 306 and is anchored to the dielectric layer 304 via the etched recess 314. Stated otherwise, the metal material 320 may be formed at least a portion of the upper surface 304u, the sidewall surface(s) 306s, and within the etch recess 314, and includes an overburden 322. The overburden 322 man include portions of the metal material 320 that covers a portion of the upper surface 304u (of field region).

At operation 225 and as illustrated in FIG. 3F the overburden 322 of the metal material 320 is removed using a CMP process. As noted above, the metal material 320 is anchored at least by the portion of the metal material 320 disposed within the anchoring regions 314a of the etched recess 314, and therefore, the formed metal material 320 will not be removed (pulled-out) during the CMP process.

While the foregoing is directed to embodiments of the present disclosure, other and further embodiments of the disclosure may be devised without departing from the basic scope thereof, and the scope thereof is determined by the claims that follow.

1. A method comprising:
exposing a semiconductor device structure to an oxidizing plasma to form an oxide layer on at least one electrical connection formed in at least one feature formed within a dielectric layer of the semiconductor device structure;
performing an etch process to remove the oxide layer and form an etch recess between a portion of the electrical connection and the dielectric layer, wherein at least a portion of the etch recess extends underneath at least a portion of the dielectric layer; and
filling the at least one feature and the etch recess with a metal material.

2. The method of claim 1, wherein the metal material fills the at least one feature, the etch recess, and includes an overburden formed on an upper surface of the dielectric layer.

3. The method of claim 2, wherein the overburden is removed using a chemical mechanic polishing (CMP) process.

4. The method of claim 1, wherein the at least one electrical connection comprises tungsten (W) and the oxide layer comprises a tungsten oxide (WOx).

5. The method of claim 4, wherein the metal material comprises molybdenum (Mo).

6. The method of claim 1, wherein the oxidizing plasma is an inductively coupled plasma (ICP) or a capacitively coupled plasma (CCP), and the oxidizing plasma is generated from hydrogen and oxygen.

7. The method of claim 6, further comprising co-flowing hydrogen and oxygen to generate the oxidizing plasma.

8. The method of claim 1, wherein the etch process comprises:
performing a chemical soaking process that comprises exposing the at least one feature to an etching gas that comprises a metal halide; and
a treatment process that comprises exposing the at least one feature to a cleaning gas that comprises hydrogen.

9. The method of claim 8, wherein the metal halide comprises at least one of: tungsten pentachloride (WCl₅), tungsten hexafluoride (WF₆), molybdenum pentachloride (MoCl₅), molybdenum hexachloride (MoCl₆), molybdenum hexafluoride (MoF₆), or combinations thereof.

10. The method of claim 9, wherein the treatment process includes treating the semiconductor device structure with a hydrogen based plasma.

11. The method of claim 1, wherein the etch process comprises:
performing a chemical soaking process that comprises exposing the at least one feature to an etching gas that comprises a metal halide; and
a treatment process that comprises a baking process that comprises heating a substrate to a temperature greater than room temperature.

12. A multi-chamber processing system comprising:
a controller; and
a memory for storing instructions, which, when executed by the controller, causes the controller to perform a method for treating an electrical connection formed in a feature formed in a dielectric layer of a semiconductor structure, the method comprising:
exposing a semiconductor device structure to an oxidizing plasma to form an oxide layer on at least one electrical connection formed in at least one feature formed within a dielectric layer of the semiconductor device structure;
performing an etch process to remove the oxide layer and form an etch recess between a portion of the electrical connection and the dielectric layer, wherein at least a portion of the etch recess extends underneath at least a portion of the dielectric layer; and
filling the at least one feature and the etch recess with a metal material.

13. The multi-chamber processing system of claim 12, wherein the oxidizing plasma is an inductively coupled plasma (ICP) or a capacitively coupled plasma (CCP) generated from hydrogen and oxygen.

14. The multi-chamber processing system of claim 12, comprises:
performing a chemical soaking process that comprises exposing the at least one feature to an etching gas that comprises a metal halide; and
a treatment process that comprises exposing the at least one feature to a cleaning gas that comprises hydrogen.

15. The multi-chamber processing system of claim 14, wherein the metal halide comprises at least one of: tungsten pentachloride (WCl₅), tungsten hexafluoride (WF₆), molybdenum pentachloride (MoCl₅), molybdenum hexachloride (MoCl₆), molybdenum hexafluoride (MoF₆), or combinations thereof.

16. The multi-chamber processing system of claim 14, wherein the treatment process includes treating the semiconductor device structure with a hydrogen based plasma.

17. The multi-chamber processing system of claim 14, wherein the treatment process includes a baking process comprising soaking the semiconductor structure in hydrogen and water and baking the semiconductor structure.

18. A semiconductor device structure comprising:
a device substrate having a frontside opposite a backside;
a dielectric layer formed over the frontside of the device substrate;
a feature formed within the dielectric layer, the feature extending through the dielectric layer and to a portion of an underlying layer that forms part of an electrical connection formed within the device substrate; and
an etch recess formed between a portion of the electrical connection and an overlying portion of the dielectric layer.

19. The semiconductor device structure of claim 18, further comprising a metal material, the metal material filling the feature and the etch recess.

20. The semiconductor device structure of claim 18, wherein the electrical connection comprises at least one of copper (Cu), cobalt (Co), molybdenum (Mo), tungsten (W), or ruthenium (Ru).
